(19) United States
(12) Patent Application Publication
(10) Pub. No.: US 2023/0364566 A1
(43) Pub. Date: Nov. 16, 2023

(54) ELECTROMAGNETIC STIRRER, ELECTROMAGNETIC MEASURING SYSTEM, MOUNTING METHOD AND ASSOCIATED MEASURING METHOD

(71) Applicant: DASSAULT AVIATION, Paris (FR)

(72) Inventors: Fabrice TRISTANT, MERIGNAC (FR); Maxime ROUSSEL, MERIGNAC (FR)

(21) Appl. No.: 18/197,951

(22) Filed: May 16, 2023

(30) Foreign Application Priority Data
May 16, 2022 (FR) FR 22 04605

(51) Int. Cl. B01F 33/453; H01Q 9/34

(52) U.S. Cl. CPC B01F 33/453; H01Q 9/34

(57) ABSTRACT

An electromagnetic stirrer includes a mast; and at least one vane presenting a surface reflecting radio and/or microwave waves, the at least one vane presenting at least two non-coplanar regions. The mast presents a vane attachment zone, and the at least one vane is attached to the vane attachment zone. At least a part of the mast and/or of the at least one vane is inflatable.

The present disclosure relates to an electromagnetic stirrer, including:
a mast;
at least one vane presenting a surface reflecting radio and/or microwave waves, the vane presenting at least two non-coplanar regions;
the mast presenting a vane attachment zone, the vane being attached to the vane attachment zone.

### BACKGROUND

Such a stirrer is intended, in particular, to be mounted in a reverberation chamber, during tests of exposure of equipment to electromagnetic fields.

Such tests are intended to measure the electromagnetic field transmitted to an equipment of a platform, in particular an equipment of an aircraft, a satellite, a land or naval vehicle. The equipment is, for example, a computer rack housed in a cargo bay of the platform.

Alternatively, the tests are intended to verify the correct operation of a platform equipment in the presence of a high intensity electromagnetic field.

In particular, the stirrer is configured to be rotated around an axis of rotation between successive measurements of the electromagnetic field received in the vicinity of the equipment or in it, from an electromagnetic field emitted in the reverberation chamber.

The equipment present in an aircraft must be protected from the external electromagnetic fields that the aircraft is subjected to. In this respect, the penetration of the electromagnetic field in the aircraft, in the vicinity of the equipment it contains, must be accurately measured during the qualification and certification of an aircraft. Indeed, it is important that this equipment, especially electronic equipment, is well protected against external electromagnetic fields so as not to cause disturbances during operation.

To perform these tests, a known method consists in placing the aircraft outside, for example on a tarmac, and in mounting antennas on the outside of the aircraft which allow the aircraft to be illuminated at different incidences, polarizations, and frequencies.

The penetration of the electromagnetic field in the cargo holds containing the equipment is measured by receivers placed inside the aircraft.

Such a method is tedious to implement, and requires favorable weather conditions.

An alternative method consists of measuring the effect of the electromagnetic field in a reverberant environment using a High Intensity Radiofrequency Field (HIRF) test. In this type of test, the platform containing the equipment to be tested is placed in a reverberation chamber presenting walls that reflect the electromagnetic field. The transmitter and the stirrer are also placed in the chamber. Measurements of the electromagnetic field received in the platform in the vicinity of the equipment are made at different angular values of the stirrer about a vertical axis, which changes the boundary conditions of the reverberation chamber and thus shifts the spatial distribution of the resonance modes within the chamber.

A known stirrer includes a central metal mast, and metal vanes permanently attached to the central mast. The vanes are angularly offset the ones relative to the others, and often comprise at least two non-coplanar surfaces.

Such a stirrer does not give complete satisfaction. Indeed, to be effective, such a stirrer must present a height close to the smallest dimension of the reverberation chamber.

For large volume chambers, which can contain, for example, a complete aircraft, the stirrer is bulky, heavy and difficult to dismantle. It is difficult to transport, and the tests must therefore always be carried out in the same chamber, by bringing the aircraft into this chamber, which can be expensive.

Moreover, such a stirrer requires a large space for its storage. Furthermore, its dimensions and shape are fixed during the design of the stirrer, so that a particular stirrer is only really suitable for a given chamber.

Such a stirrer is also usually quite fragile, requiring specific means and skills to handle and repair it. It often presents sharp metal edges that can create risks of injury when handled.

One aim of the present disclosure is to provide a particularly efficient electromagnetic stirrer to allow measurements in a reverberation chamber by generating a homogeneous and isotropic electromagnetic field, the electromagnetic stirrer being easy to handle and adaptable.

### SUMMARY

To this end, the present disclosure provides an electromagnetic stirrer of the aforementioned type, wherein at least a part of the mast and/or of the or each vane is inflatable.

The electromagnetic stirrer according to the present disclosure may comprise one or more of the following features, taken alone or in any technically possible combination:
the or each vane is inflatable;
it comprises a system for removably attaching the or each vane to the vane attachment zone;
the attachment system includes a zipper;
the or each vane presents a side edge, the or each vane being attached along its side edge to the vane attachment zone;
it comprises a plurality of inflatable vanes presenting different dimensions, the vane attachment zone being configured to interchangeably accommodate multiple vanes of the plurality of inflatable vanes, each vane being configured to be mounted in place of another vane on the vane attachment zone;
the inflatable vane presents at least one region with a C-shaped cross-section, for example, a single region having a C-shaped cross-section, or a plurality of regions with a C-shaped cross-section arranged adjacent to each other;
the inflatable vane includes an inflatable framework and at least one radio and/or microwave electromagnetic wave reflecting layer carried by the inflatable framework;
the framework includes at least two inflatable peripheral uprights and at least one inflatable crosspiece connecting the inflatable peripheral uprights together;
the mast is inflatable;
the mast is cylindrical with a vertical axis, the vane attachment zone extending along a generatrix of the mast;
it includes a turntable, the mast carrying the or each vane being configured to be mounted on the turntable to be driven in rotation about a vertical axis by the turntable.

The present disclosure also has as its object an electromagnetic measuring and/or testing system including:
a reverberation chamber;
a radio and/or microwave electromagnetic wave transmitter intended to be placed in the reverberation chamber;
optionally an electromagnetic wave receiver intended to be placed in the vicinity of equipment placed in the reverberation chamber; and
an electromagnetic stirrer as defined above intended to be placed in the reverberation chamber.

The present disclosure also has as its object a method of mounting an electromagnetic stirrer, including the following steps:
providing a mast and at least one vane presenting a surface reflecting radio and/or microwave waves, the vane presenting at least two non-coplanar regions;
the mast presenting a vane attachment zone, the vane being attached to the vane attachment zone, at least a part of the mast and/or of the or each vane being inflatable;
the inflatable part of the mast and/or of the or each vane being initially deflated, the method including a step of inflating the inflatable part of the mast and/or the or each vane.

The assembly method according to the present disclosure may comprise the following features:

the mast and/or the or each vane is inflatable, the providing step including providing the mast and/or the or each vane in a deflated and disassembled configuration, the method comprising assembling the or each vane to the mast before inflation, and inflating the mast and/or the or each vane after assembly.

The present disclosure also has as its object a measurement method for electromagnetic measuring and/or testing including the following steps:
providing a reverberation chamber:
implementation of a method for mounting an electromagnetic stirrer and arrangement of the electromagnetic stirrer in the reverberation chamber;
arrangement of a transmitter in the reverberation chamber, and;
emission of radio and/or microwave electromagnetic waves from the transmitter into the reverberation chamber;
placing a receiver in the reverberation chamber in the vicinity of an equipment to be tested in the reverberation chamber and measuring the electromagnetic field received by the receiver, and/or
testing an equipment in operation in the reverberation chamber;
the method including a step of rotating the electromagnetic stirrer around an axis of rotation between two successive measurements of the electromagnetic field received by the receiver or between two successive tests of the equipment in operation.

### BRIEF DESCRIPTION OF THE DRAWINGS

The present disclosure will be better understood upon reading the following description, given by way of example only, and made with reference to the attached drawings, in which:

FIG. 1 is a schematic view of a first electromagnetic measuring and/or test system according to the present disclosure, comprising an inflatable electromagnetic stirrer arranged in a reverberation chamber;

FIG. 2 is a schematic view of the inflatable parts of the stirrer including the mast and a vane;

FIG. 3 is a schematic side view of sections of different vanes that can be interchangeably mounted on the mast of the stirrer in FIG. 2;

FIG. 4 is a curve showing the standard deviation on the values of the three components of the electromagnetic field in the reverberation chamber after a full rotation of the stirrer in the chamber.

### DETAILED DESCRIPTION

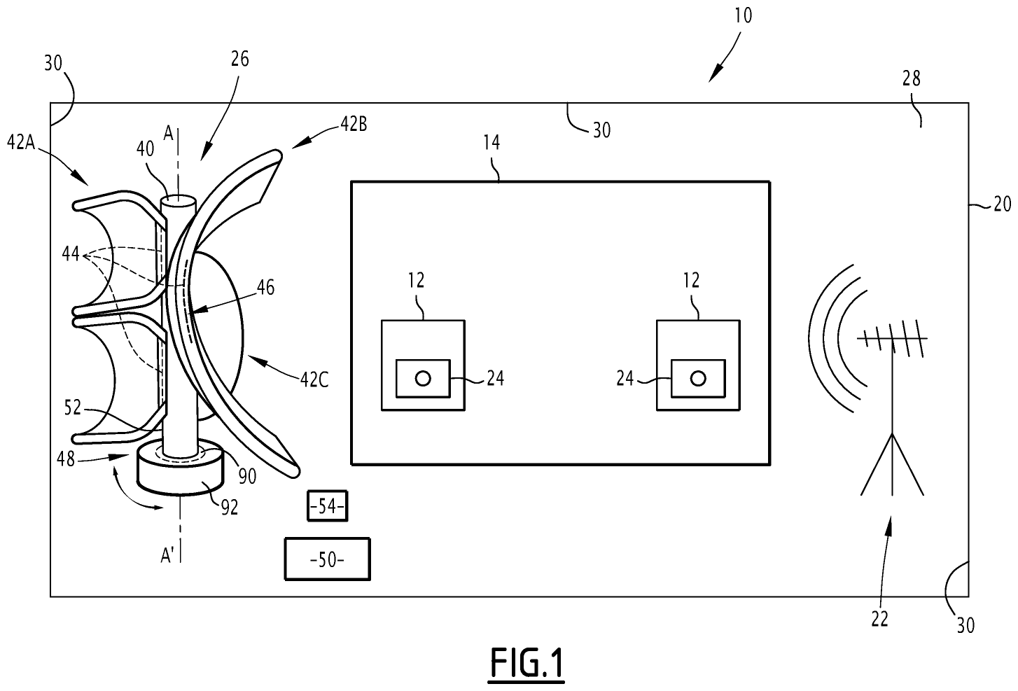

FIG. 1 illustrates a first electromagnetic measuring and/or test system 10, intended to generate an electromagnetic field and to measure the electromagnetic field received by an equipment 12 arranged within a platform 14, as shown in FIG. 1, and/or to test the operating performance of the equipment 12 in the presence of the received electromagnetic field (in particular when the emitted electromagnetic field presents a high intensity, in particular between a few V/m and a few kV/m, for example 100 V/m, “High Intensity Radiated Field” or HIRF).

The measuring system 10 is intended, in particular, to test the protection of the equipment 12 provided by the platform 14 with respect to the electromagnetic field received, and/or the performance of the equipment 12 and more generally of the platform 14 in operation, when the platform 14 including its equipment 12 is subjected to this electromagnetic field.

In one particular case, the measuring system 10 is intended to measure the transfer function of the electromagnetic field as a function of frequency, through the walls of the platform 14, and possibly through electromagnetic protection barriers provided within the platform 14, in particular in a cargo hold of the platform 14.

The equipment 12 is, for example, a computer, a sensor, a computer rack or any onboard aeronautical equipment, arranged in the platform 14. The platform 14 is in particular an aircraft, in particular a civil or military aircraft, in particular an aircraft or a drone.

With reference to FIG. 1, the measurement system 10 includes a reverberation chamber 20 inside which measurements are carried out.

The measuring system 10 also comprises an electromagnetic field transmitter 22 arranged in the reverberation chamber 20, outside the platform 14 and at least one electromagnetic field receiver 24 arranged in the vicinity or in the equipment 12, within the platform 14.

The measuring system 10 further includes an electromagnetic stirrer 26 according to the present disclosure, arranged in the reverberation chamber 20, the electromagnetic stirrer 26 being at least partially inflatable.

The stirrer 26 is intended to be rotated about a vertical axis A-A′ between two electromagnetic field measurements in order to change the boundary conditions of the reverberation chamber 20, and to homogenize the average of the electromagnetic field and its maximum value at all points of the reverberation chamber 20 and to rotate the electromagnetic field along all polarizations.

The reverberation chamber 20 defines an internal volume 28 configured to contain the platform 14 receiving the equipment 12.

The internal volume 28 is for example greater than 1 m³ and in particular between 2 m³ and 10,000 m³, in particular between 1,000 m³ and 5,000 m³ for example 3,000 m³.

The reverberation chamber 20 is, for example, a fixed chamber provided within a building, in particular a hangar, delimited by reflective surfaces 30.

Alternatively, the reverberation chamber 20 is a removable chamber, preferably inflatable. In this case, it includes inflatable pillars and beams connecting the pillars, the pillars and beams supporting reflective surfaces 30 delimiting the internal volume 28.

The reflective surfaces 30 are configured to reflect the electromagnetic field at least partially in the range of wavelengths of emission of this electromagnetic field by the transmitter 22 which will be specified below.

The reflective surfaces 30 are, for example, metallic surfaces, in particular formed by a metallic layer arranged on a deformable support, in particular a film, for example of plastic or a fabric. The reflective surfaces 30 are attached to the pillars and beams of the reverberation chamber 20. By deformable, it is meant in particular that the support can be folded by hand by a user.

The transmitter 22 includes at least one antenna configured to emit an electromagnetic field at a frequency in the radio and/or microwave wave range.

The frequency of the emitted electromagnetic field is for example between 10 kHz and 40 GHz, preferably between 100 MHz and 18 GHz for the example shown. Such a range of frequencies covers a large part of the electromagnetic fields to which an aircraft is subjected when it is on the ground or in flight.

Each receiver 24 is configured to be arranged in the vicinity of or in the equipment 12 within the platform 14 to measure the electromagnetic field experienced by the equipment 12.

Each receiver 24 is, for example, arranged in a cargo hold of the platform 14.

When the platform 14 is an aircraft, the cargo bay is, in particular, a technical cargo bay containing the electrical equipment and computers of the aircraft. The technical bay is, for example, equipped with electromagnetic protection barriers.

The receiver 24 is configured to measure the intensity, frequency and/or phase of the electromagnetic field received through the platform 14 in the vicinity of or in the equipment 12 to allow the calculation of a transfer function between the field emitted by the transmitter 22 and the field received by the receiver 24.

As previously indicated, the electromagnetic stirrer 26 is configured to allow, by successive rotations about its axis A-A′, the creation of a homogeneous and isotropic electromagnetic field at all points of the internal volume 28 of the reverberation chamber 20.

The electromagnetic stirrer 26 is here at least partially inflatable. In this example, it comprises an inflatable mast 40, at least one inflatable vane 42A to 42E, removably and interchangeably mounted on at least one attachment zone 44 of the mast, and a system 46 for removably attaching each vane 42A to 42E to the attachment zone 44 of the mast 40.

Alternatively, the mast 40 is not inflatable, only the vanes 42A to 42E are inflatable.

The electromagnetic stirrer 26 further includes a system 48 for driving the inflatable parts of the electromagnetic stirrer 26 in rotation about the vertical axis A-A′, these inflatable parts including the mast 40 and the or each vane 42A to 42C carried by the mast 40.

In the example shown in FIG. 1, the inflatable parts of the electromagnetic stirrer 26 are shown in an inflated and mounted configuration, the inflatable mast 40 being assembled on the system 48 for driving the mast in rotation.

The inflatable parts of the electromagnetic stirrer 26 are configured to transition into a deflated and disassembled configuration, in which the inflatable parts of the electromagnetic stirrer 26 including here the mast 40 and each vane 42A to 42B, are deflated and disassembled, thereby occupying a minimal volume.

Thus, the electromagnetic stirrer 26 advantageously further includes a bag 50 intended to receive the inflatable parts of the electromagnetic stirrer 26 in their deflated configuration. The volume occupied by the inflatable parts of the electromagnetic stirrer 26 in their deflated configuration is less than 1 m³, allowing them to be easily carried in the bag 50.

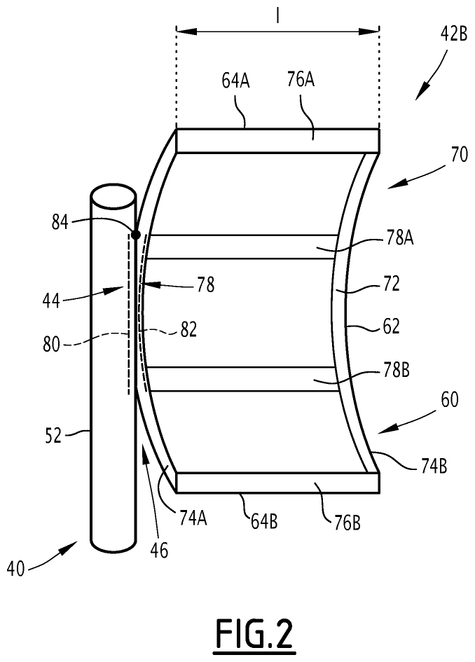

With reference to FIG. 2, the mast 40 is here formed by a cylindrical pillar 52 of vertical axis A-A′.

The pillar 52 defines a plurality of attachment zones 44 angularly spaced about the axis A-A′, each attachment zone 44 extending substantially along a distinct generatrix of the cylindrical pillar 52.

In the inflated configuration, the height of the pillar 52 is, for example, greater than 50 cm, and in particular between 1 m and 10 m. The diameter of the pillar is, for example, greater than 10 cm, and is in particular between 20 cm and 1 meter.

Advantageously, the pillar 52 is formed of at least one inflatable bladder presenting a sealed wall. The interior volume of the pillar 52 is configured to be inflated to a pressure greater than atmospheric pressure, for example by an air compressor 54.

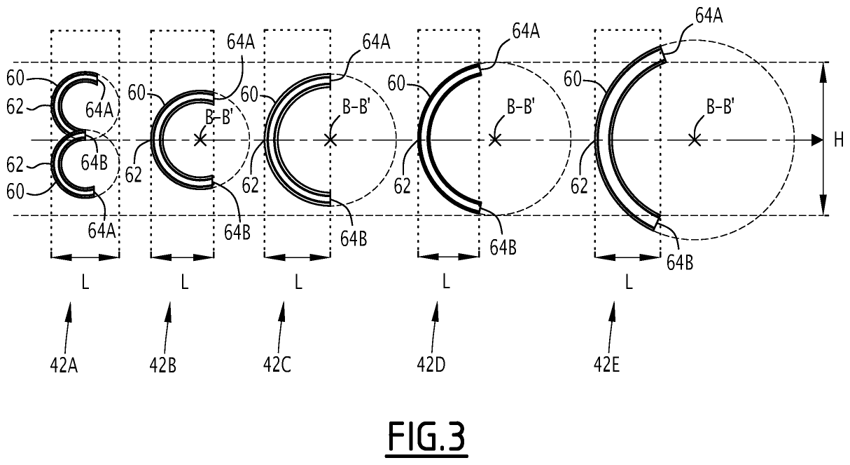

In the example shown in FIGS. 1 and 3, the inflatable stirrer 26 includes a plurality of inflatable vanes 42A to 42E, configured to be interchangeably mounted on an attachment zone 44 of the inflatable mast 40.

The vanes 42A to 42E present different geometries, in particular different heights, and/or different curvatures.

Each vane 42A to 42E is non-planar. It thus presents at least two non-coplanar regions.

In the example shown in FIGS. 1 to 3, each vane 42A to 42E presents a shape of a section of a cylinder cut along a plane parallel to the B-B′ axis of the cylinder.

Each vane 42A to 42E thus presents at least one region 60 of C-shaped cross-section, taken perpendicular to the cylinder axis.

At least one vane 42A presents two C-shaped cross-sectional regions 60 adjacent to each other, here mounted the one on the other by a common edge.

In the example shown in FIG. 3, the lengths L of the vanes 42A to 42E taken horizontally between their vertices 62, and their free edges 64A, 64B are substantially equal. The length of each vane 42A to 42E is for example between 1 m and 3 m, for example equal to 2 m.

The width I of each vane 42A to 42E (see FIG. 2), taken along the axis B-B′ of the cylinder, is for example between 0.2 m and 5 m, for example equal to 3 m.

The height H of each vane 42A to 42E, taken vertically between the free edges 64A, 64B depends on the radius of curvature of the section in C of each vane 42A to 42E. The radius of curvature of the C-shaped section is, for example, greater than 0.5 m, and is particularly between 2 m and 10 m, more particularly between 2 m and 6 m.

In this example, as illustrated in FIG. 2, each vane 42B includes an inflatable framework 70, and at least one reflective surface 72 carried by the inflatable framework 70.

The inflatable framework 70 includes at least one inflatable bladder, preferably a plurality of inflatable bladders, delimiting the lateral uprights 74A, 74B, and at least one crosspiece 76A, 76B. The uprights 74A, 74B and crosspieces 76A, 76B define the periphery of the vane 42B and a central space.

Advantageously, the inflatable framework 70 further includes at least one auxiliary crosspiece 78A, 78B, preferably a plurality of auxiliary crosspieces 78A, 78B connecting the uprights 74A, 74B through the central space.

The or each bladder is formed by a sealed bag, configured to be inflated to a pressure greater than the atmospheric pressure, for example by the air compressor 54.

The reflective surface 72 is configured to reflect the electromagnetic field at least partially in the range of wavelength emissions of that electromagnetic field by the transmitter 22. Thus, the reflective surface 72 is configured to, at least partially, reflect the radio and/or microwave electromagnetic waves emitted by the transmitter 22, or reflected by the platform 14 and/or by the equipment 12.

The reflecting surface 72 is for example a metallic surface, in particular formed by a metallic layer arranged on a deformable support, in particular a film, for example of plastic or a fabric. The reflective surface 72 is attached to the inflatable framework 70.

Preferably, the reflective surface 72 completely covers at least one main face of the vane 42B between the uprights 74A, 74B and the crosspieces 76A, 76B, here the rear main face. Advantageously, at least one other reflective surface 72 covers a front main face of the vane 42B

In this example, each upright 74A, 74B is C-shaped. At least one uprights 74A, 74B laterally defines a complementary zone 78 for attachment to the mast, intended to be removably assembled on the attachment zone 44 of the mast 40.

The complementary attachment zone 78 being substantially vertical, it extends correspondingly to the attachment zone 44, ensuring pseudo-coplanarity between the zones 44 and 78 during attachment by the removable attachment system 46.

Thus, the vane 42B can be mounted vertically on the mast 40 with the C-shaped section opening horizontally.

The removable attachment system 46 is, for example, formed by a zipper (commonly referred to as a “zip”). It includes in particular a zipper system comprising a first track 80 integral with the attachment zone 44, a second track 82 integral with the complementary attachment zone 78, and a member 84 for assembling the tracks 80, 82.

The assembly member 84 is permanently engaged on one of the tracks 80, 82. It is configured to engage at one end of the other track 82, 80, to reversibly assemble the tracks 80, 82 one on top of the other by displacement of the assembly member 84 along the tracks 80, 82.

The system 48 for driving in rotation is visible, for example, in FIG. 1. It includes a turntable 90, and optionally a motor 92.

The motor 92 is configured to drive the turntable 90 in rotation about the vertical axis A-A′ in increments, in particular in increments of between 1° and 30°, and then to stop once the increment has been completed to allow electromagnetic field measurements to be taken at each receiver 24.

It is configured to jointly drive in rotation the inflatable parts of the electromagnetic stirrer 26, including the mast 40, and the vanes 42A to 42C carried by the mast 40 over an angular displacement of at least 360° about the axis A-A′.

A method for mounting and positioning the electromagnetic stirrer 26 will now be described.

Initially, the reverberation chamber 20 is already present, for example within a building. Alternatively, the reverberation chamber 20 is mounted, for example by inflating the pillars and beams, causing the reflective intermediate surfaces 30 to unfold.

The electromagnetic stirrer 26 is then brought into the internal volume 28. Its inflatable parts are initially deflated and folded up to be contained, for example, in the bag 50.

Advantageously, the system 48 for driving in rotation is placed on the floor of the chamber 20.

The mast 40 and a set of vanes 42A to 42C are removed from the bag 50.

Preferably, a part of the vanes 42A to 42C from among all of the vanes 42A to 42E available in the set of vanes 42A to 42E are selected to be mounted on the mast 40, depending particularly on the dimensions of the reverberation chamber 20.

Preferably, the selected vanes 42A to 42C are previously assembled on the mast 40, when the mast 40 and the vanes 42A to 42C are in their deflated configuration.

For this purpose, the complementary attachment zone 78 of each vane 42A to 42C is brought into the vicinity of a respective attachment zone 44 of the mast 40, and the tracks 80, 82 are joined to each other, by displacement of the assembly member 84.

The attachment of the vanes 42A to 42C in the deflated configuration facilitates the placement and assembly of the track 80 to the complementary track 82 and compensates for the pseudo-coplanarity between the attachment zone 44 and the complementary attachment zone 78.

Then, the bladders of the mast 40 and the inflatable framework 70 of each vane 42A to 42C are inflated. The mast 40 erects, and the vanes 42A to 42C deploy radially away from the mast 40. The mast 40 and each vane 42A, 42B extend vertically. Each vane 42A to 42B opens horizontally facing a respective angular sector about the axis A-A′.

The mast 40 is assembled by its lower end on the turntable 90. The electromagnetic stirrer 26 is then ready for use.

The platform 14 receiving the equipment is introduced into the internal volume 28 as well as the transmitter 22, before, during or after the assembly of the electromagnetic stirrer 26.

The or each receiver 24 is placed close to or in the equipment 12 within the platform 14.

To perform the measurements, the electromagnetic stirrer 26 is successively rotated incrementally about its axis A-A′ by successive rotations of the turntable 90.

Between each rotation of the electromagnetic stirrer 26, the transmitter 22 is activated to emit electromagnetic waves at a plurality of given frequencies in the aforementioned frequency range.

Each receiver 24 measures the intensity, frequency and/or phase of the electromagnetic waves received in the vicinity of or in each piece of equipment 12 for each angular orientation of the electromagnetic stirrer 26, and for each frequency of transmission.

As mentioned above, over one revolution of the electromagnetic stirrer 26, the maximum and average value of the electromagnetic field is identical at all points of the reverberation chamber 20 and the electromagnetic field has rotated along all polarizations.

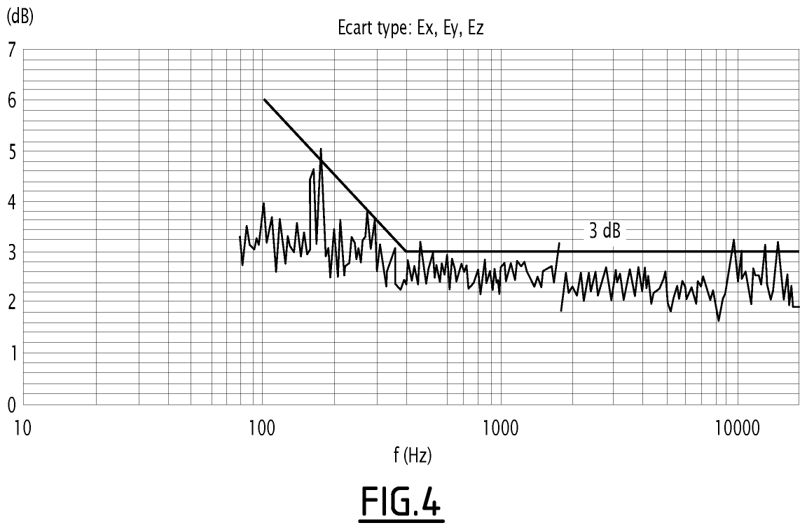

The isotropy of the electromagnetic field can be verified by calculating the standard deviation of the EX, EY and EZ components of the electromagnetic field at several points of the reverberation chamber 20, this standard deviation being less than 3 dB for the horizontal part, as seen in FIG. 4.

The electromagnetic stirrer 26 according to the present disclosure thus makes it possible to carry out measurement campaigns quickly and efficiently, whatever the weather conditions, by producing a very homogeneous electromagnetic field within the reverberation chamber 20.

The inflatable parts of the electromagnetic stirrer 26 are then deflated and stored, for example, in its bag 50, with a view to being transported to another site to carry out another measurement campaign.

In addition, if one of the vanes 42A, 42B, 42C needs to be changed, it can be easily removed from the mast 40, by disengaging the complementary track 82 from the track 80 by displacement of the assembly member 84, then assembling another vane, for example the vane 42D, in place of the vane 42C. This allows for a great deal of modularity in the dimensions and structure of the electromagnetic stirrer 26, depending on the size of the internal volume 28 to be stirred.

The at least partially inflatable electromagnetic stirrer 26 according to the present disclosure is thus very simple to use, and not very bulky to store. It is robust and not very fragile. It also presents a low cost, and is very light, for example less than 15 kg

Its assembly and disassembly is very fast, in less than an hour, in particular of the order of fifteen minutes.

It presents vanes 42A to 42D presenting an original shape, which produce an efficient mixing of the electromagnetic field, avoiding cuts or injuries to the operators.

The presence of a metallic layer on the vanes 42A to 42E and on the mast 40 ensures an efficient reflection of the electromagnetic waves in the whole radio and microwave field.

It is also not necessary to ensure electrical continuity between the mast 40 and each vane 42A to 42E of the electromagnetic stirrer 26 to guarantee its proper operation.

The electromagnetic stirrer 26 is scalable, the shape of the vanes 42A to 42E being easily changed by making vanes of different shapes, for example, elliptical or circular, with the help of other bladders, and then assembling these vanes to the inflatable mast 40.

Such an electromagnetic stirrer 26 can therefore be readily used to certify and/or recertify aircraft in a variety of locations. The electromagnetic stirrer 26 can be used for military or civilian aircraft, or even for electromagnetic testing to be performed on other equipment 12, possibly present in other platforms, in particular satellites, naval platforms, or land-based platforms such as automobiles.

What is claimed is:

1. An electromagnetic stirrer comprising:
a mast; and
at least one vane presenting a surface reflecting radio and/or microwave waves, the at least one vane presenting at least two non-coplanar regions;
the mast presenting a vane attachment zone, the at least one vane being attached to the vane attachment zone;
at least a part of the mast and/or of the at least one vane being inflatable.

2. The electromagnetic stirrer according to claim 1, wherein the at least one vane is inflatable.

3. The electromagnetic stirrer according to claim 2, further comprising a removable attachment to attach the at least one vane to the vane attachment zone.

4. The electromagnetic stirrer according to claim 3, wherein the removable attachment comprises a zipper.

5. The electromagnetic stirrer according to claim 2, wherein the at least one vane presents a side edge, the at least one vane being attached along its side edge to the vane attachment zone.

6. The electromagnetic stirrer according to claim 2, including a plurality of inflatable vanes presenting different dimensions, the vane attachment zone being configured to interchangeably accommodate several vanes among the plurality of inflatable vanes, each vane of the several vanes being configured to be mounted as a replacement for another vane of the several vanes on the vane attachment zone.

7. The electromagnetic stirrer according to claim 2, wherein the at least one inflatable vane presents at least one region having a C-shaped cross-section.

8. The electromagnetic stirrer according to claim 2, wherein the at least one inflatable vane includes an inflatable framework and at least one layer reflecting radio and/or microwave electromagnetic waves, the at least one layer being carried by the inflatable framework.

9. The electromagnetic stirrer according to claim 8, wherein the inflatable framework includes at least two inflatable peripheral uprights and at least one inflatable crosspiece connecting the inflatable peripheral uprights.

10. The electromagnetic stirrer according to claim 1, wherein the mast is inflatable.

11. The electromagnetic stirrer according to claim 10, wherein the mast is cylindrical with a vertical axis, the vane attachment zone extending along a generatrix of the mast.

12. The electromagnetic stirrer according to claim 1, further comprising a turntable, the mast carrying the at least one vane being configured to be mounted on the turntable to be driven in rotation about a vertical axis by the turntable.

13. An electromagnetic measuring and/or test system including:
a reverberation chamber;
a transmitter of radio and/or microwave electromagnetic waves configured to be placed in the reverberation chamber; and
the electromagnetic stirrer according to claim 1, configured to be placed in the reverberation chamber.

14. The electromagnetic measuring and/or test system according to claim 13, further comprising an electromagnetic wave receiver configured to be placed in a vicinity of an equipment placed in the reverberation chamber.

15. A mounting method to mount an electromagnetic stirrer, comprising:
providing a mast and at least one vane presenting a surface reflecting radio and/or microwave waves, the at least one vane presenting at least two non-coplanar regions,
the mast presenting a vane attachment zone, the at least one vane being attached to the vane attachment zone, at least a part of the mast and/or of the at least one vane being inflatable,
the inflatable part of the mast and/or of the at least one vane being initially deflated; and
inflating the inflatable part of the mast and/or of the at least one vane.

16. The method according to claim 15, wherein the mast and/or the at least one vane is inflatable, providing a mast and at least one vane including providing the mast and/or the at least one vane in a deflated and disassembled configuration, the method comprising assembling the at least one vane to the mast prior to inflation of the mast and/or the at least one vane, and inflating the mast and/or the at least one vane after assembling the at least one vane to the mast.

17. An electromagnetic measuring and/or test method, comprising:
providing a reverberation chamber:
implementing the mounting method according to claim 15, and arranging the electromagnetic stirrer in the reverberation chamber;
arranging a transmitter in the reverberation chamber,
transmitting electromagnetic radio waves and/or microwaves from the transmitter into the reverberation chamber;
placing a receiver in the reverberation chamber in a vicinity of an equipment to be tested in the reverberation chamber and measuring an electromagnetic field received by the receiver and/or testing an equipment in operation in the reverberation chamber; and
rotating the electromagnetic stirrer about an axis of rotation between two successive measurements of the electromagnetic field received by the receiver or between two successive tests of the equipment in operation.
